(19) United States
(12) Patent Application Publication
(10) Pub. No.: US 2006/0273423 A1
(43) Pub. Date: Dec. 7, 2006

(54) Chip resistor and method for manufacturing same

(75) Inventor: Torayuki Tsukada, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto (JP)

(21) Appl. No.: 10/552,301

(22) PCT Filed: Apr. 7, 2004
(86) PCT No.: PCT/JP04/05038

§ 371 Date: Oct. 7, 2005

(30) Foreign Application Priority Data
Apr. 8, 2003 (JP) 2003-103843

(51) Int. Cl. H01L 29/00

(52) U.S. Cl. 257/516

(57) ABSTRACT

A chip resistor (A1) includes a resistor element (1) including an electrode forming surface (10b), two electrodes (3) provided at the electrode-forming surface (10b), and an insulating layer (2A) provided at the electrode-forming surface (10b). The electrode-forming surface (10b) includes an inter-electrode region positioned between the two electrodes (3) and covered by the insulating layer (2A). The insulating layer (2A) has a thickness (t2) which is equal or generally equal to the thickness (t1) of the electrodes (3).

### TECHNICAL FIELD

The present invention relates to a chip resistor and a method for manufacturing the same.

### BACKGROUND ART

FIG. 11 of the present application shows the prior art chip resistor disclosed in JP-A 2002-57009. The chip resistor includes a resistor element 90 made of metal, and a pair of electrodes 91 provided at the lower surface of the resistor element. The electrodes 91 are spaced from each other by a predetermined distance S₆. Each of the electrodes 91 has a lower surface formed with a solder layer 92.

The prior art chip resistor is manufactured by the method shown in FIG. 12. First, two metal plates 90′ and 91′ are prepared (ST1), and the metal plate 90′ is bonded to the upper surface of the metal plate 91′ (ST2). Subsequently, the metal plate 91′ is partially cut away by machining to form a gap 93 (ST3). Then, a solder layer 92′ is formed on the lower surface of the metal plate 91′ (ST4). As a result, an intermediate assembly made up of the metal plates 90′, 91′ and the solder layer 92′ is obtained. Finally, the intermediate assembly is cut to provide an intended chip resistor (ST5).

The above chip resistor has the following drawback. As shown in FIG. 11, the resistor element 90 of the chip resistor is supported by the electrodes 91 spaced from each other. With such a structure, the chip resistor 90 may bend or break when an impact force is applied to the center portion of the chip resistor. Such an impact force may be generated in automatically mounting the chip resistor on a circuit board by using a suction collet, for example.

### DISCLOSURE OF THE INVENTION

The present invention is conceived under the circumstances described above. It is, therefore, an object of the present invention to provide a chip resistor which is not damaged even when such an impact force as described above is applied to the chip resistor. Another object of the present invention is to provide a method for manufacturing such a chip resistor.

According to a first aspect of the present invention, there is provided a chip resistor comprising: a resistor element including an electrode forming surface, at least two electrodes provided at the electrode forming surface, and an insulating layer provided at the electrode forming surface. The electrode-forming surface includes an inter-electrode region positioned between the two electrodes and covered by the insulating layer. The insulating layer has a thickness which is equal or generally equal to a thickness of the electrodes.

Preferably, the thickness of the insulating layer is smaller than the thickness of the electrodes. The difference between the thickness of the insulating layer and the thickness of the electrodes is so set that, when the resistor element flexes upon receiving a load, the insulating layer comes into contact with a flat mount surface before the resistor element is damaged.

Preferably, the thickness of the insulating layer is smaller than the thickness of the electrodes. The difference between the thickness of the insulating layer and the thickness of the electrodes is set to be smaller than the maximum deflection δₘₐₓ of the resistor element when the maximum bending stress σₘₐₓ produced in the resistor element reaches the elastic limit σ_{y} of the resistor element.

Preferably, the insulating layer is formed by thick film printing.

According to a second aspect of the present invention, there is provided a method for manufacturing a chip resistor comprising the steps of pattern-forming an insulating layer on an electrode forming surface of a resistor element material, forming a conductive layer on the electrode forming surface at a region where the insulating layer is not formed, the conductive layer having a thickness which is equal or generally equal to a thickness of the insulating layer, and dividing the resistor element material into a plurality of resistor elements each in the form of a chip. The division of the resistor element material is so performed that each of the resistor elements in the form of a chip includes part of the insulating layer and electrode portions spaced from each other by the part of the insulating layer.

Preferably, the pattern-forming of the insulating layer is performed by thick film printing.

Preferably, the formation of the conductive layer is performed by plating.

Preferably, the division of the resistor element material is performed by punching or cutting.

### BRIEF DESCRIPTION OF THE DRAWINGS

FIG. 1 is perspective view showing a chip resistor according to a first embodiment of the present invention.

FIG. 2 is a sectional view taken along lines II-II in FIG. 1.

FIGS. 3A-3C are perspective views showing part of process steps of a method for manufacturing the chip resistor.

FIGS. 4A and 4B are perspective views showing the process steps to be performed after the process step shown in FIG. 3C.

FIG. 5 is a perspective view showing part of process steps of another method for manufacturing the chip resistor.

FIGS. 6A and 6B are perspective views showing the process steps to be performed after the process step shown in FIG. 5.

FIG. 7 is a sectional view showing a chip resistor according to a second embodiment of the present invention.

FIG. 8A is a sectional view showing a chip resistor according to a third embodiment of the present invention.

FIG. 8B is a bottom view showing the chip resistor of the third embodiment.

FIG. 9A is a sectional view showing a chip resistor according to a fourth embodiment of the present invention.

FIG. 9B is a bottom view showing the chip resistor of the fourth embodiment.

FIG. 10 is a perspective view showing a chip resistor according to a fifth embodiment of the present invention.

FIG. 11 is a perspective view showing a prior art chip resistor.

FIG. 12 shows a method for manufacturing the prior art chip resistor.

### BEST MODE FOR CARRYING OUT THE INVENTION

Preferred embodiments of the present invention will be described below with reference to the accompanying drawings.

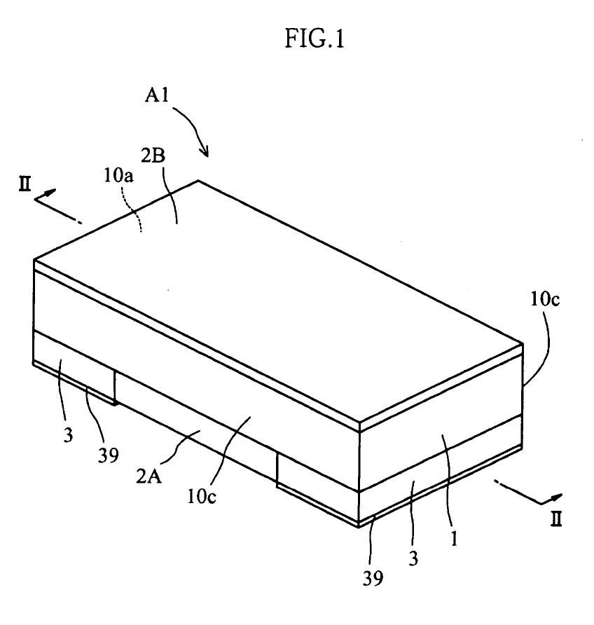

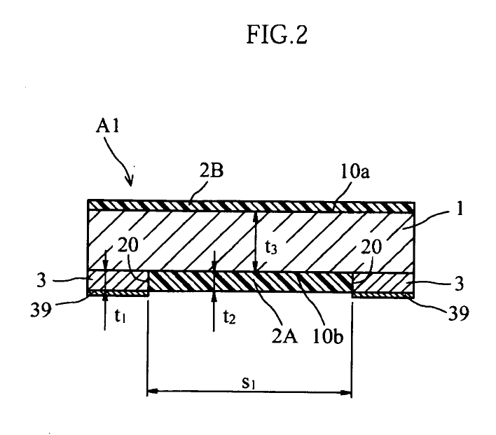

FIGS. 1 and 2 show a chip resistor according to a first embodiment of the present invention. The illustrated chip resistor A1 includes a resistor element 1, a first insulating layer 2A, a second insulating layer 2B and a pair of electrodes 3.

The resistor element 1 has an elongated rectangular configuration and has a uniform thickness. The resistor element 1 can be made of a metal material such as Ni—Cu-based alloy, Cu—Mn-based alloy and Ni—Cr-based alloy. The metal material for making the resistor element is not limited to these, and other metal material may be used as long as it has a resistivity suitable for the size and the intended resistance of the chip resistor A1.

The first and the second insulating layers 2A and 2B are made of epoxy resin, for example. The first insulating layer 2A is formed on the lower surface (electrode forming surface) 10b of the resistor element 1, whereas the second insulating layer 2B is formed on the upper surface 10a of the resistor element 1. Specifically, the lower surface 10b of the resistor element 1 is made up of regions formed with electrodes 3 and the remaining region (hereinafter referred to as “inter-electrode region”). The first insulating layer 2A covers the entirety of the inter-electrode region. The second insulating layer 2B covers the entirety of the upper surface 10a of the resistor element 1.

The paired electrodes 3 are spaced from each other in the longitudinal direction of the resistor element 1. Each of the electrodes 3 is made of copper, for example. As shown in FIG. 2, each electrode 3 adjoins an end surface 20 of the first insulating layer 2A. Therefore, the distance between the two electrodes 3 is equal to the length s₁ of the first insulating layer 2A. Each of the electrodes 3 has a lower surface formed with a solder layer 39 for providing good solderability. For instance, the resistance of the chip resistor A1 (resistance between the paired electrodes 3) is set to the range of 1 mΩ to 100 mΩ.

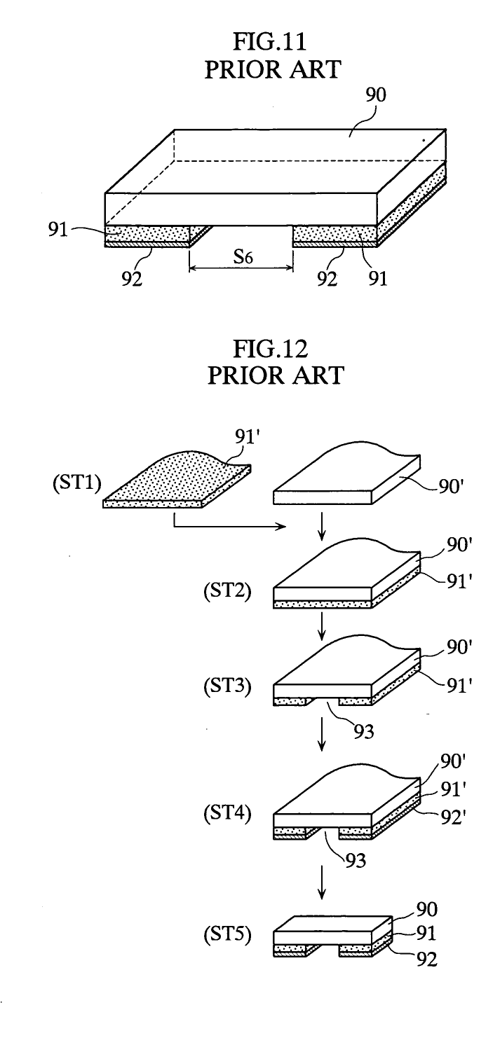

The thickness t₁ of the electrodes 3 and the thickness t₂ of the first insulating layer 2A are equal or generally equal to each other. With such a structure, the resistor element 1 can be supported by the two electrodes 3 and the insulating layer 2A. Therefore, as compared with the prior art chip resistor (FIG. 11), the chip resistor A1 of the present invention is unlikely to be damaged even when an impact force is applied to the center portion of the resistor element 1.

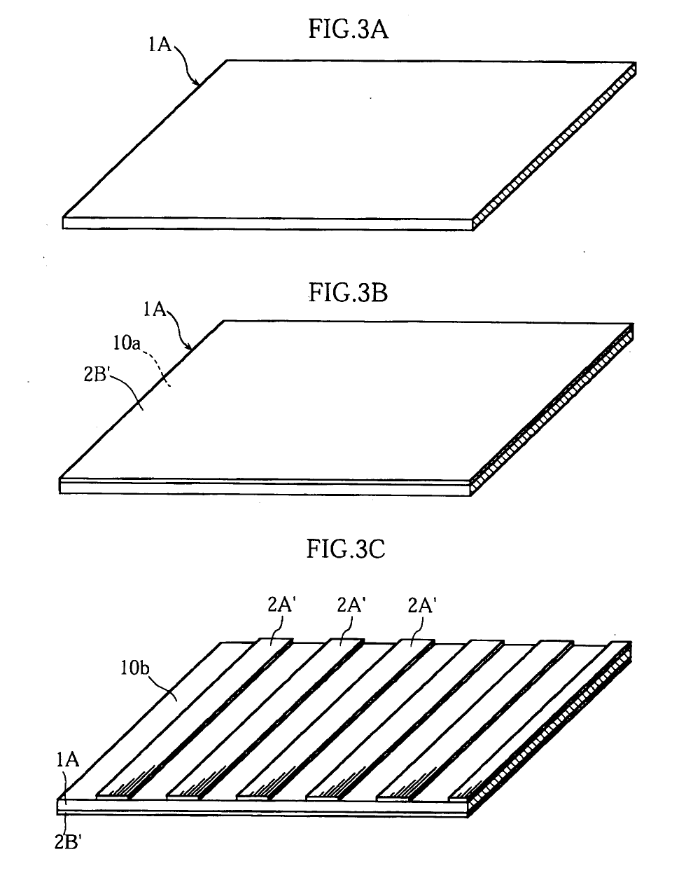

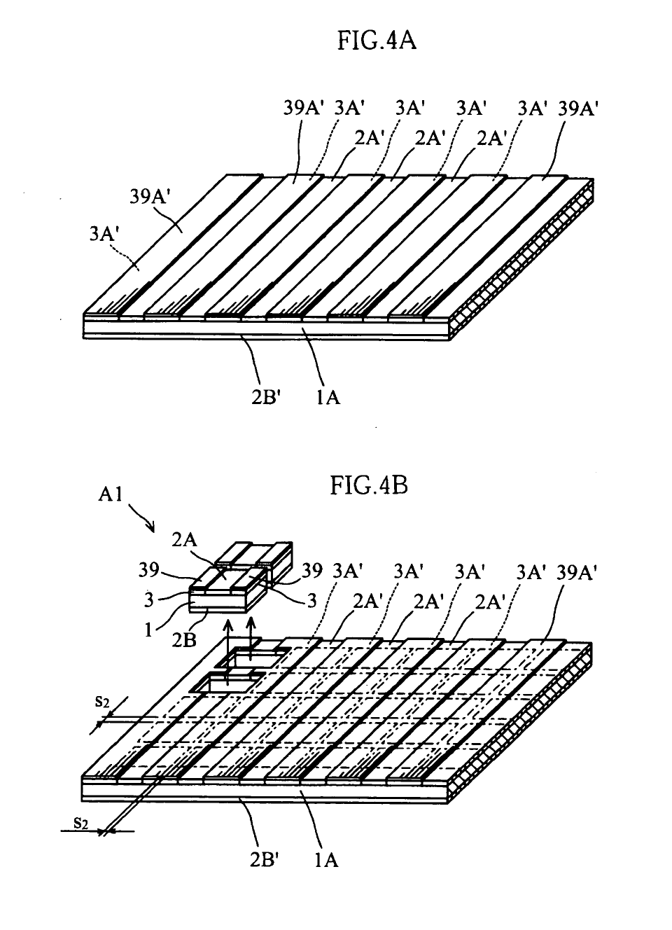

Next, a method for manufacturing the chip resistor A1 will be described with reference to FIGS. 3A-3C and 4A-4B.

First, as shown in FIG. 3A, a plate 1A made of metal and having a uniform thickness throughout the entirety is prepared. The plate 1A has a size (length×width) capable of providing a plurality of resistor elements 1. As shown in FIG. 3B, an insulating layer 2B′ is formed to cover the entirety of the upper surface 10a of the plate 1A. The insulating layer 2B′ may be formed by thick film printing of epoxy resin, for example. On the obverse surface of the insulating film 2B′ thus formed, marks may be formed, as required. Subsequently, as shown in FIG. 3C, a plurality of insulating strips 2A′ extending parallel to each other are formed on the lower surface 10b of the plate 1A. The insulating strips 2A′ are spaced from each other by a predetermined distance in the lateral direction in the figure. The insulating strips 2A′ is formed by thick film printing using the same resin material and apparatus used for forming the insulating layer 2B′. By thick film printing, each of the insulating strips 2A′ can be precisely formed into a predetermined size (particularly, width). Further, the thickness of each insulating strips 2A′ can be easily adjusted.

Subsequently, as shown in FIG. 4A, conductive layers 3A′ are formed at regions between adjacent insulating strips 2A′. Then, solder layers 39A′ are formed on the respective conductive layers 3A′. The conductive layers 3A′ are the base to become electrodes 3 and may be formed by copper plating, for example. By the plating process, it is possible to prevent a gap from being formed between each of the conductive layers 3A′ and the adjacent insulating strip 2A′. Therefore, the spacing between adjacent conductive layers 3A′ becomes equal to the width of each insulating strip 2A′. As noted above, each insulating strip 2A′ is precisely formed into a predetermined width by thick film printing. Therefore, the spacing between adjacent conductive layers 3A′ (and hence, the spacing between a pair of electrodes 3) can be precisely formed into a predetermined dimension. Further, in the plating process, the thickness of each conductive layer 3A′ can be controlled by adjusting the processing time. Therefore, the thickness of each electrode 3 and that of the first insulating layer 2A can be easily made generally equal to each other. The solder layers 39A′ can also be made by plating process.

As shown in FIG. 4B, after the above plating process, punching is repetitively performed with respect to the plate 1A. Preferably, in the punching, a single punching die (not shown) is repetitively used. By this process, a plurality of identical resistor elements can be obtained from the plate 1A. Specifically, the punching is performed with respect to each of rectangular regions indicated in FIG. 4B (by single-dot chain lines). The rectangular regions are arranged in a matrix, and adjacent rectangular regions are spaced from each other by a predetermined distance s₂. As shown in the figure, the center portion of each of the rectangular regions overlaps the insulating strip 2A′, whereas two end portions flanking the center portion overlap the solder layers 39A′. By performing punching with respect to such rectangular regions, intended chip resistors A1 can be obtained.

As compared with the prior art manufacturing method (FIG. 12), the above method for manufacturing a chip resistor has the following advantages. In the prior art method, the metal plate 91′ is mechanically cut (ST3 in FIG. 12) to provide a pair of electrodes 91 spaced from each other. The spacing distance between the two electrodes 91 (S6 in FIG. 11) has an influence on the resistance of the chip resistor. Therefore, to adjust the resistance to an intended value, the cutting of the metal plate 91′ need be performed precisely. Since such cutting operation need be performed carefully and takes a long time, the productivity of the chip resistor is deteriorated. In the manufacturing method of the present invention, as described with reference to FIG. 4A, the spacing distance between the paired electrodes 3 can be set precisely and extremely easily by the plating process.

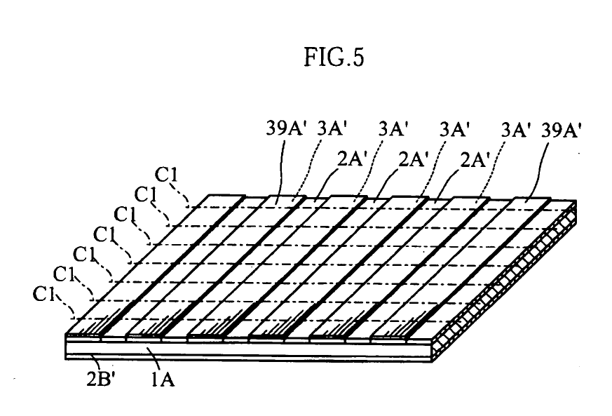

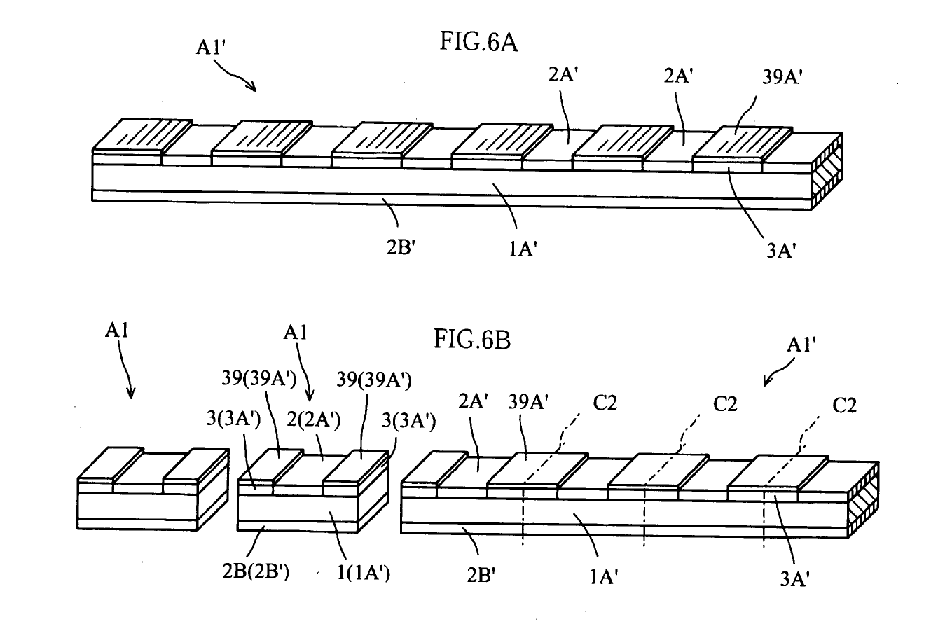

In the present invention, to obtain a plurality of resistor elements from the plate 1A, cutting means such as a shearing machine or a rotary cutter may be used instead of the above-described punching (See FIG. 4B). In this case, the plate 1A shown in FIG. 4A is first cut along the cutting lines C1 indicated in FIG. 5. (Each of the cutting lines C1 extends perpendicularly to the longitudinal direction of the insulating strips 2A′ and the conductive layers 3A′). As a result, a plurality of resistor aggregates A1′ each in the form of a bar as shown in FIG. 6A are obtained. Subsequently, as shown in FIG. 6B, each of the resistor aggregates A1′ is cut along the cutting lines C2. As a result, a plurality of chip resistors A1 are obtained from a single resistor aggregate A1′.

The chip resistor A1 of the present invention can be surface-mounted on a circuit board by reflow soldering, for example. Specifically, the chip resistor A1 is placed on the circuit board so that each electrode 3 (solder layer 39) comes into contact with a terminal provided on the circuit board. In this state, the circuit board and the chip resistor A1 are heated in a reflow oven. Thereafter, the molten solder is cooled for hardening, whereby the chip resistor A1 is fixed to the circuit board.

Generally, in surface-mounting a chip resistor by reflow soldering, molten solder may be pressed out from between the electrode of the resistor and the circuit board. In such a case, in the prior art chip resistor (FIG. 11), the molten solder may adhere to the lower surface of the resistor element 90 (inter-electrode region), which may hinder the obtaining of a predetermined resistance. However, in the chip resistor A1 (FIGS. 1 and 2) of the present invention, the inter-electrode region of the resistor element 1 is covered by the first insulating layer 2A. Therefore, molten solder does not adhere to the inter-electrode region.

Further, the upper surface 10a of the chip resistor A1 is covered by the second insulating layer 2B. With such a structure, the upper surface 10a is prevented from undesirably coming into contact with another conductive member.

In the present invention, the thickness t₂ of the first insulating layer 2A and the thickness t₁ of the electrode 3 are made equal or generally equal to each other. In the latter case, either t₂ is greater than t₁ (t₂>t₁) or the reverse (t₂<t₁). In the case where t₂>t₁, t₂ is so set that the first insulating layer 2A does not project downward beyond the lower surface of the solder layer 39, for example. In the case where t₂<t₁, t₂ is set within the range described below. First, the chip resistor A1 is regarded as a simple beam (opposite ends of the resistor element 1 are supported by the paired electrodes 3). The resistor element 1 is assumed to resiliently deform by receiving uniformly distributed load. In this case, the maximum bending stress σₘₐₓ and the maximum deflection δₘₐₓ produced in the resistor element 1 are given by the following formulae 1 and 2.

$$\begin{matrix}{σ}_{max} = \frac{w {l}^{2}}{8 Z} & ( 1 ) \\ {δ}_{max} = \frac{5 w \cdot {s}_{1}^{4}}{384 EI} & ( 2 )\end{matrix}$$

where w is the uniformly distributed load to be exerted to the resistor element 1, E is the longitudinal elastic modulus of the resistor element 1, s₁ is the dimension between the electrodes 3, Z and I are respectively the modulus of section and the geometrical moment of inertia of the resistor element 1 which are defined by the following formulae 3 and 4.

$$\begin{matrix}Z = \frac{1}{6} b \cdot {t}_{3}^{2} & ( 3 ) \\ I = \frac{1}{12} b \cdot {t}_{3}^{3} & ( 4 )\end{matrix}$$

where b is the width of the resistor element 1, and t₃ is the thickness of the resistor element 1. From the formulae 1 through 4, the maximum deflection δₘₐₓ when the maximum bending stress σₘₐₓ reaches the elastic limit σ_{y} is obtained and represented as the formula 5 below.

$${δ}_{max} = \frac{5}{24} \cdot \frac{{σ}_{y}}{E} \cdot \frac{{s}_{1}^{2}}{{t}_{3}} \qquad ( 5 )$$

When the thickness t₂ is smaller than the thickness t₁, the thicknesses are so set that the relation represented by the following formula 6 be established. When the difference between the thicknesses t₁ and t₂ lies in the range represented by the formula 6, the inter-electrode region of the resistor element 1 flexes until the surface of the first insulating layer 2A becomes flush with the electrodes 3 and is thereafter supported by the mount surface of the circuit board (on the assumption that the mount surface of the circuit board is flat). Therefore, the maximum bending stress σ max produced in the resistor element 1 does not reach the elastic limit σ_{y}, so that the resistor element 1 is prevented from being damaged.

$${t}_{1} - {t}_{2} < \frac{5}{24} \cdot \frac{{σ}_{y}}{E} \cdot \frac{{s}_{1}^{2}}{{t}_{3}} \qquad ( 6 )$$

The “elastic limit” in the present invention means yield stress in the case of iron and steel materials, and 0.2% proof stress in the case of non-ferrous materials. In the above embodiment, materials such as Ni—Cu-based alloy, Cu—Mn-based alloy and Ni—Cr-based alloy for forming the resistor element 1 are non-ferrous materials. Therefore, as the elastic limit σ_{y} it is proper to use 0.2% proof stress of these materials.

Examples of values to be assigned to the right side of the above formula 6 are as follows. The dimension s₁ (between the electrode 3)=5 mm, the thickness t₃ (of the resistor element 1)=0.5 mm, the longitudinal modulus E (of the resistor element 1)=130 GPa, and the 0.2% proof stress σ_{y}=360 MPa. In this case, from the formula 6, t₁-t₂ is found to be no greater than about 30 μm. It is to be noted that the values herein described are merely examples, and values need be set appropriately with respect to each individual chip resistor. In the value setting, the material of the resistor element, the size of the chip resistor, the positional relationship with the object for mounting (e.g. circuit board), the reference amount for defining the damage to the resistor element 1 (e.g. flexed amount, stress) are considered, for example.

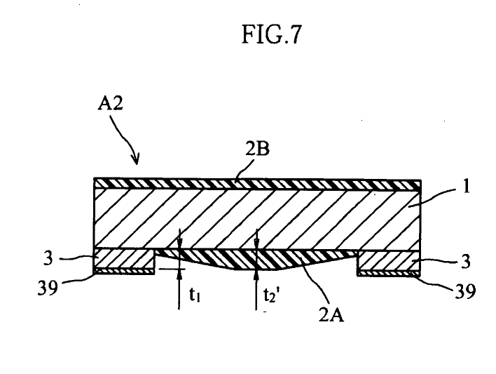

FIG. 7 shows a chip resistor A2 according to a second embodiment of the present invention. The chip resistor A2 has the same structure as that of the chip resistor A1 of the first embodiment except the following points. In the first embodiment, the first insulating layer 2A has a uniform thickness. In the second embodiment, the thickness of the first insulating layer 2A is not uniform. Specifically, as shown in FIG. 7, the first insulating layer 2A of the second embodiment is trapezoidal in section. The thickness at the center portion of the trapezoid (i.e. the maximum thickness of the first insulating layer) t2′ is equal or generally equal to the thickness t1 of the third electrodes 3. Also with such a structure, the paired electrodes 3 and the first insulating layer 2A can bear the impact force applied to the chip resistor A2.

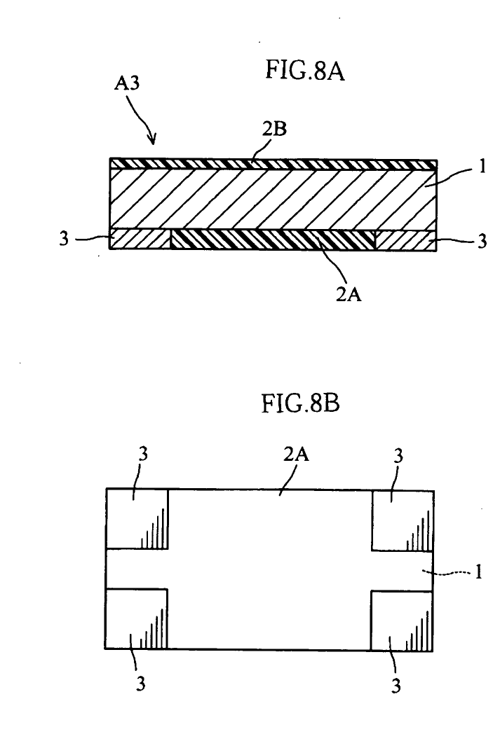

FIGS. 8A and 8B show a chip resistor A3 according to a third embodiment of the present invention. As will be understood from FIG. 8B, in the chip resistor A3, four electrodes 3 are provided on the lower surface of the resistor element 1. Of the lower surface of the resistor element 1, the regions at which the four electrodes 3 are not provided are covered by the first insulating layer 2A. Other structures of the chip resistor A3 are substantially the same as the chip resistor A1 of the first embodiment.

For example, the chip resistor A3 can be used as follows. Among the four electrodes 3, two electrodes 3 are used as current electrodes, whereas the other two electrodes 3 are used as voltage electrodes. In the current detection of an electric circuit, the pair of current electrodes 3 is connected in series to the current path of the electric circuit. To the pair of voltage electrodes 3, a voltmeter is connected. Since the resistance of the chip resistor A3 is known, the voltage drop at the resistor element 1 of the chip resistor A3 is measured by using the voltmeter. By applying the measured value to the Ohm's law formula, the current flowing through the resistor element 1 can be found.

In the chip resistor of the present invention, more than four electrodes may be provided. For example, in the case where the number of electrodes is increased, only some of the electrodes may be used.

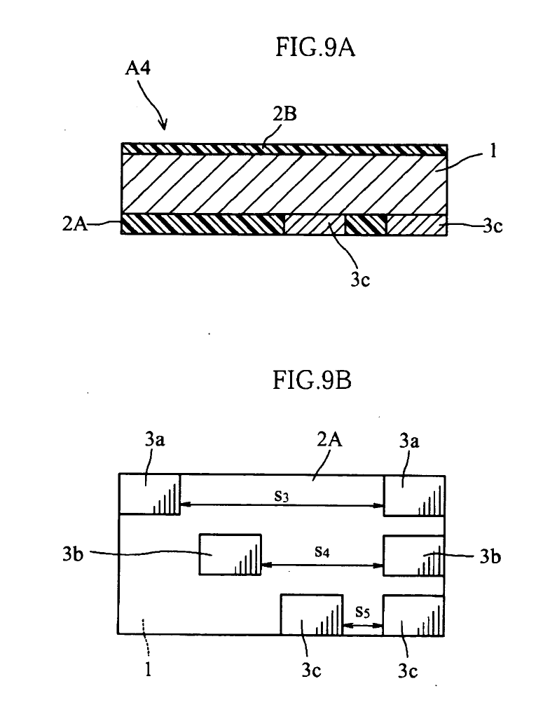

FIGS. 9A and 9B show a chip resistor A4 according to a fourth embodiment of the present invention. As shown in FIG. 9B, the lower surface of the resistor element 1 is provided with three pairs of electrodes 3a, 3b and 3c. The electrodes 3a of the first pair are spaced from each other by a distance s₃. Similarly, the electrodes 3b of the second pair are spaced from each other by a distance s₄, and the electrodes 3c of the third pair are spaced from each other by a distance s₅. Although these distances are so set to satisfy s₃>s₄>s₅ in the illustrated example, the present invention is not limited thereto. Further, although the right one of each pair of electrodes 3a-3c is arranged along the right edge of the resistor element 1, the electrodes may be arranged otherwise.

The above chip resistors A3 and A4 can be manufactured by a method similar to the method for manufacturing the chip resistor A1 of the first embodiment. With the method, the insulating layer 2A′ as the base to become the insulating layer 2A is formed into a pattern by a thick film printing. Therefore, it is possible to provide insulating layers which match various patterns of electrodes 3 of different number, configuration and arrangement.

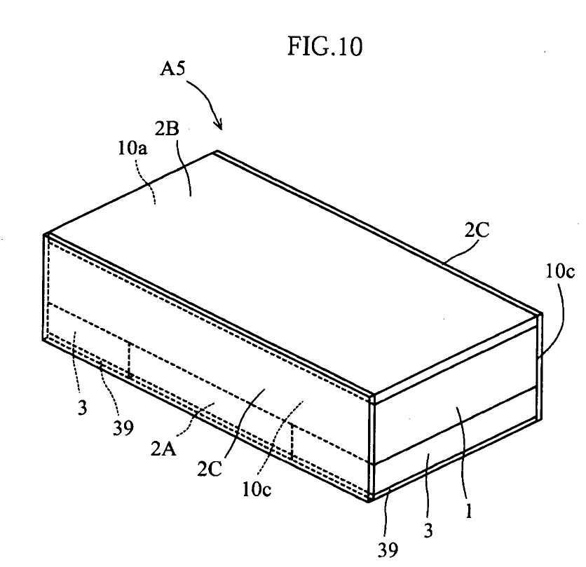

FIG. 10 shows a chip resistor A5 according to a fifth embodiment of the present invention. The structure of the chip resistor A5 is basically the same as that of the chip resistor A1 of the first embodiment except that third insulating layers 2C for covering two opposite side surfaces 10c of the resistor element 1 are provided. With such a structure, the adhesion of e.g. molten solder to the side surfaces 10c can be prevented. The third insulating layer 2C can be easily provided by forming an insulating layer on a side surface of the resistor element material 1A′ in the form of a bar shown in FIG. 6A.

The present invention being thus described, it is apparent that the same may be varied in many ways. Such variations should not be regarded as a departure from the spirit and scope of the present invention, and all such modifications as would be obvious to those skilled in the art are intended to be included within the scope of the following claims.

1. A chip resistor comprising:
a resistor element including an electrode-forming surface;
at least two electrodes provided at the electrode forming surface; and
an insulating layer provided at the electrode-forming surface;
wherein the electrode-forming surface includes an inter-electrode region positioned between the two electrodes and covered by the insulating layer, and wherein the insulating layer has a thickness which is equal or generally equal to a thickness of the electrodes.

2. The chip resistor according to claim 1, wherein the thickness of the insulating layer is smaller than the thickness of the electrodes, and wherein difference between the thickness of the insulating layer and the thickness of the electrodes is so set that, when the resistor element flexes upon receiving a load, the insulating layer comes into contact with a flat mount surface before the resistor element is damaged.

3. The chip resistor according to claim 1, wherein the thickness of the insulating layer is smaller than the thickness of the electrodes, and wherein difference between the thickness of the insulating layer and the thickness of the electrodes is set to be smaller than maximum deflection δₘₐₓ of the resistor element when maximum bending stress σₘₐₓ produced in the resistor element reaches elastic limit σ_{y} of the resistor element.

4. The chip resistor according to claim 1, wherein the insulating layer is formed by thick film printing.

5. A method for manufacturing a chip resistor, the method comprising the steps of:
pattern-forming an insulating layer on an electrode-forming surface of a resistor element material;
forming a conductive layer on the electrode-forming surface at a region where the insulating layer is not formed, the conductive layer having a thickness which is equal or generally equal to a thickness of the insulating layer; and
dividing the resistor element material into a plurality of resistor elements each in the form of a chip;
wherein the division of the resistor element material is so performed that each of the resistor elements in the form of a chip includes part of the insulating layer and electrode portions spaced from each other by the part of the insulating layer.

6. The manufacturing method according to claim 5, wherein the pattern-forming of the insulating layer is performed by thick film printing.

7. The manufacturing method according to claim 5, wherein the formation of the conductive layer is performed by plating.

8. The manufacturing method according to claim 5, wherein the division of the resistor element material is performed by punching.

9. The manufacturing method according to claim 5, wherein the division of the resistor element material is performed by cutting.
